(19) United States
(12) Patent Application Publication
(10) Pub. No.: US 2025/0103779 A1
(43) Pub. Date: Mar. 27, 2025

(54) LEARNING UNSUPERVISED WORLD MODELS FOR AUTONOMOUS DRIVING VIA DISCRETE DIFFUSION

(71) Applicant: WAABI Innovation Inc., Toronto (CA)

(72) Inventors: Lunjun ZHANG, Toronto (CA); Yuwen XIONG, Toronto (CA); Ze YANG, Toronto (CA); Sergio CASAS ROMERO, Toronto (CA); Raquel URTASUN, Toronto (CA)

(73) Assignee: WAABI Innovation Inc., Toronto (CA)

(21) Appl. No.: 18/900,601

(22) Filed: Sep. 27, 2024

Related U.S. Application Data
(60) Provisional application No. 63/585,945, filed on Sep. 27, 2023.

(51) Int. Cl. G06F 30/27; B60W 50/00; B60W 60/00

(52) U.S. Cl. CPC G06F 30/27; B60W 50/0097; B60W 60/001

(57) ABSTRACT

A method learns unsupervised world models for autonomous driving via discrete diffusion. The method includes encoding an observation of an actor for a geographic region using an encoder to generate a prior frame of prior tokens. The method further includes processing the prior frame with a spatio-temporal transformer to generate a predicted frame of predicted tokens. The spatio-temporal transformer includes a spatial transformer and a temporal transformer. The method further includes processing the predicted frame to generate a predicted action for the actor. The method further includes decoding the predicted frame to generate a predicted observation of the geographic region.

### CROSS REFERENCE TO RELATED APPLICATIONS

This application claims the benefit of U.S. Provisional Application No. 63/585,945, filed Sep. 27, 2023, which is hereby incorporated by reference herein.

### BACKGROUND

Learning world models can teach an agent how the world works in an unsupervised manner. World modeling may be viewed as a special case of sequence modeling. Progress for scaling world models on robotic applications such as autonomous driving has been somewhat less rapid than scaling language models with generative pre-trained transformers (GPTs). Two reasons may include dealing with complex and unstructured observation space and having a scalable generative model.

### SUMMARY

In general, in one or more aspects, the disclosure relates to a method that implements learning unsupervised world models for autonomous driving via discrete diffusion. The method includes encoding an observation of an actor for a geographic region using an encoder to generate a prior frame of prior tokens. The method further includes processing the prior frame with a spatio-temporal transformer to generate a predicted frame of predicted tokens. The spatio-temporal transformer includes a spatial transformer and a temporal transformer. The method further includes processing the predicted frame to generate a predicted action for the actor. The method further includes decoding the predicted frame to generate a predicted observation of the geographic region.

In general, in one or more aspects, the disclosure relates to a system that includes at least one processor and an application that executes on the at least one processor. Executing the application performs encoding an observation of an actor for a geographic region using an encoder to generate a prior frame of prior tokens. Executing the application further performs processing the prior frame with a spatio-temporal transformer to generate a predicted frame of predicted tokens. The spatio-temporal transformer includes a spatial transformer and a temporal transformer. Executing the application further performs processing the predicted frame to generate a predicted action for the actor. Executing the application further performs decoding the predicted frame to generate a predicted observation of the geographic region.

In general, in one or more aspects, the disclosure relates to a non-transitory computer readable medium including instructions executable by at least one processor. Executing the instructions performs encoding an observation of an actor for a geographic region using an encoder to generate a prior frame of prior tokens. Executing the instructions further performs processing the prior frame with a spatio-temporal transformer to generate a predicted frame of predicted tokens. The spatio-temporal transformer includes a spatial transformer and a temporal transformer. Executing the instructions further performs processing the predicted frame to generate a predicted action for the actor. Executing the instructions further performs decoding the predicted frame to generate a predicted observation of the geographic region.

Other aspects of one or more embodiments may be apparent from the following description and the appended claims.

### BRIEF DESCRIPTION OF DRAWINGS

FIG. 1 shows a diagram of an autonomous training and testing system in accordance with the disclosure.

FIG. 2 shows a diagram of a simulation system in accordance with the disclosure.

FIG. 3, FIG. 4, and FIG. 5 show systems in accordance with the disclosure.

FIG. 6 shows a method in accordance with the disclosure.

FIG. 7, FIG. 8, FIG. 9, and FIG. 10, show examples in accordance with the disclosure.

FIG. 11A and FIG. 11B show a computing system in accordance with the disclosure.

Similar elements in the various figures may be denoted by similar names and reference numerals. The features and elements described in one figure may extend to similarly named features and elements in different figures.

### DETAILED DESCRIPTION

Embodiments of the disclosure learn supervised world models for autonomous driving via discrete diffusion to address the issues of complex and unstructured observation space with a scalable generative model. The world modeling approach may first tokenize sensor observations (e.g., with a vector quantized variational autoencoder VQVAE), then predict the future via discrete diffusion. To efficiently decode and denoise tokens in parallel, a masked generative image transformer (MGIT) may be recast into a discrete diffusion framework with a few changes, resulting in notable improvement. The improvements to machine learning models of the disclosure include the use of multiple branches in a decoder for a variational autoencoder and include performing diffusion steps on the output of a transformer model. When applied to learning world models on point cloud observations, the improved machine learning model may unlock the power of GPT-like unsupervised learning for robotic agents with improved and more accurate predictions of observations and corresponding actions to take in response to the observations.

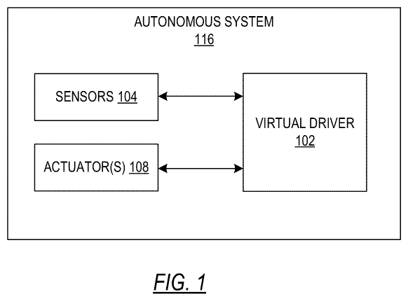

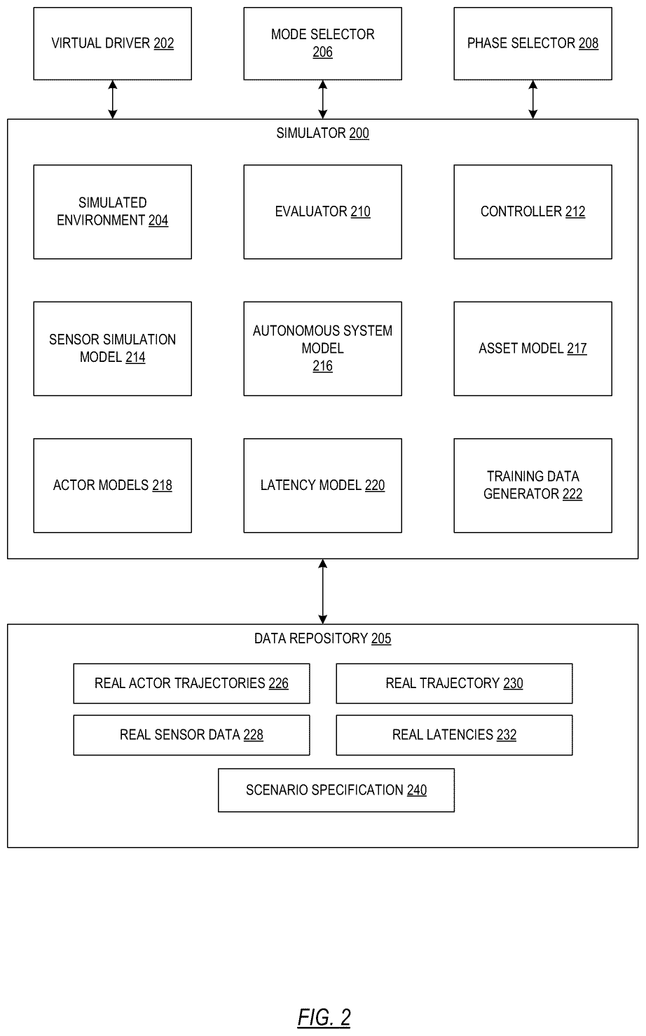

Turning to the figures, FIG. 1 and FIG. 2 show example diagrams of the autonomous system and virtual driver. Turning to FIG. 1, an autonomous system (116) is a self-driving mode of transportation that does not require a human pilot or human driver to move and react to the real-world environment. The autonomous system (116) may be completely autonomous or semi-autonomous. As a mode of transportation, the autonomous system (116) is contained in a housing configured to move through a real world environment. Examples of autonomous systems include self-driving vehicles (e.g., self-driving trucks and cars), drones, airplanes, robots, etc.

The autonomous system (116) includes a virtual driver (102) that is the decision making portion of the autonomous system (116). The virtual driver (102) is an artificial intelligence system that learns how to interact in the real world and interacts accordingly. The virtual driver (102) is the software executing on a processor that makes decisions and causes the autonomous system (116) to interact with the real world including moving, signaling, and stopping, or maintaining a current state. Specifically, the virtual driver (102) is decision making software that executes on hardware (not shown). The hardware may include a hardware processor, memory or other storage device, and one or more interfaces. A hardware processor is any hardware processing unit that is configured to process computer readable program code and perform the operations set forth in the computer readable program code.

A real world environment is the portion of the real world through which the autonomous system (116), when trained, is designed to move. Thus, the real world environment may include concrete and land, construction, and other objects in a geographic region along with agents. The agents are the other agents in the real world environment that are capable of moving through the real world environment. Agents may have independent decision making functionality. The independent decision-making functionality of the agent may dictate how the agent moves through the environment and may be based on visual or tactile cues from the real world environment. For example, agents may include other autonomous and non-autonomous transportation systems (e.g., other vehicles, bicyclists, robots), pedestrians, animals, etc.

In the real world, the geographic region is an actual region within the real world that surrounds the autonomous system. Namely, from the perspective of the virtual driver, the geographic region is the region through which the autonomous system moves. The geographic region includes agents and map elements that are located in the real world. Namely, the agents and map elements each have a physical location in the geographic region that denotes a place in which the corresponding agent or map element is located. The map elements are stationary in the geographic region, whereas the agents may be stationary or nonstationary in the geographic region. The map elements are the elements shown in a map (e.g., road map, traffic map, etc.) or derived from a map of the geographic region.

The real world environment changes as the autonomous system (116) moves through the real world environment. For example, the geographic region may change and the agents may move positions, including new agents being added and existing agents leaving.

In order to interact with the real world environment, the autonomous system (116) includes various types of sensors (104), such as LiDAR sensors amongst other types, which are used to obtain measurements of the real world environment, and cameras that capture images from the real world environment. The autonomous system (116) may include other types of sensors as well. The sensors (104) provide input to the virtual driver (102).

In addition to sensors (104), the autonomous system (116) includes one or more actuators (108). An actuator is hardware and/or software that is configured to control one or more physical parts of the autonomous system based on a control signal from the virtual driver (102). In one or more embodiments, the control signal specifies an action for the autonomous system (e.g., turn on the blinker, apply brakes by a defined amount, apply accelerator by a defined amount, turn the steering wheel or tires by a defined amount, etc.). The actuator(s) (108) are configured to implement the action. In one or more embodiments, the control signal may specify a new state of the autonomous system and the actuator may be configured to implement the new state to cause the autonomous system to be in the new state. For example, the control signal may specify that the autonomous system should turn by a certain amount while accelerating at a predefined rate, while the actuator determines and causes the wheel movements and the amount of acceleration on the accelerator to achieve a certain amount of turn and acceleration rate.

The testing and training of a virtual driver of the autonomous systems in the real world environment is unsafe because of the accidents that an untrained virtual driver can cause. Thus, as shown in FIG. 2, a simulator (200) is configured to train and test a virtual driver (202) of an autonomous system. Once trained, the virtual driver (202) may be deployed to a real world system, such as the autonomous system (116) of FIG. 1.

The simulator (200) may be a unified, modular, mixed reality, closed loop simulator that generates a world model for autonomous systems. The simulator (200) is a configurable simulation framework that enables not only evaluation of different autonomy components in isolation, but also as a complete system in a closed loop manner. The simulator reconstructs “digital twins” of real world scenarios automatically, enabling accurate evaluation of the virtual driver at scale. The simulator (200) may also be configured to generate the world model as a mixed reality simulation that combines real world data and simulated data to create diverse and realistic evaluation variations to provide insight into the virtual driver's performance. The mixed reality closed loop simulation allows the simulator (200) to analyze the virtual driver's action on counterfactual “what-if” scenarios that did not occur in the real world. The simulator (200) further includes functionality to simulate and train on rare yet safety-critical scenarios with respect to the entire autonomous system and closed loop training to enable automatic and scalable improvement of autonomy.

The simulator (200) creates the simulated environment (204) that is a part of the world model forming a virtual world in which the virtual driver (202) is the player in the virtual world. The simulated environment (204) is a simulation of a real world environment, which may or may not be in actual existence, in which the autonomous system is designed to move. As such, the simulated environment (204) includes a simulation of the objects (i.e., simulated objects or assets) and background in the real world, including the natural objects, construction, buildings and roads, obstacles, as well as other autonomous and non-autonomous objects. The simulated environment simulates the environmental conditions within which the autonomous system may be deployed. Additionally, the simulated environment (204) may be configured to simulate various weather conditions that may affect the inputs to the autonomous systems. The simulated objects may include both stationary and non-stationary objects. Non-stationary objects are actors in the real world environment.

The simulator (200) also includes an evaluator (210). The evaluator (210) is configured to train and test the virtual driver (202) by creating various scenarios in the simulated environment. Each scenario is a configuration of the simulated environment including, but not limited to, static portions, movement of simulated objects, actions of the simulated objects with each other and reactions to actions taken by the autonomous system and simulated objects. The evaluator (210) is further configured to evaluate the performance of the virtual driver using a variety of metrics.

The evaluator (210) assesses the performance of the virtual driver throughout the performance of the scenario. Assessing the performance may include applying rules. For example, the rules may be that the automated system does not collide with any other actor, compliance with safety and comfort standards (e.g., passengers not experiencing more than a certain acceleration force within the vehicle), the automated system not deviating from an executed trajectory, or other rule. Each rule may be associated with the metric information that relates a degree of breaking the rule with a corresponding score. The evaluator (210) may be implemented as a data-driven neural network that learns to distinguish between good and bad driving behavior. The various metrics of the evaluation system may be leveraged to determine whether the automated system satisfies the requirements of success criterion for a particular scenario. Further, in addition to system level performance, for modular based virtual drivers, the evaluator may also evaluate individual modules such as segmentation or prediction performance for actors in the scene with respect to the ground truth recorded in the simulator.

The simulator (200) is configured to operate in multiple phases as selected by the phase selector (208) and modes as selected by a mode selector (206). The phase selector (208) and mode selector (206) may be a graphical user interface or application programming interface component that is configured to receive a selection of phase and mode, respectively. The selected phase and mode define the configuration of the simulator (200). Namely, the selected phase and mode define which system components communicate and the operations of the system components.

The phase may be selected using a phase selector (208). The phase may be a training phase or a testing phase. In the training phase, the evaluator (210) provides metric information to the virtual driver (202), which uses the metric information to update the virtual driver (202). The evaluator (210) may further use the metric information to further train the virtual driver (202) by generating scenarios for the virtual driver. In the testing phase, the evaluator (210) does not provide the metric information to the virtual driver. In the testing phase, the evaluator (210) uses the metric information to assess the virtual driver and to develop scenarios for the virtual driver (202).

The mode may be selected by the mode selector (206). The mode defines the degree to which real world data is used, whether noise is injected into simulated data, degree of perturbations of real world data, and whether the scenarios are designed to be adversarial. Example modes include open loop simulation mode, closed loop simulation mode, single module closed loop simulation mode, fuzzy mode, and adversarial mode. In an open loop simulation mode, the virtual driver is evaluated with real world data. In a single module closed loop simulation mode, a single module of the virtual driver is tested. An example of a single module closed loop simulation mode is a localizer closed loop simulation mode in which the simulator evaluates how the localizer estimated pose drifts over time as the scenario progresses in simulation. In a training data simulation mode, the simulator is used to generate training data. In a closed loop evaluation mode, the virtual driver and simulation system are executed together to evaluate system performance. In the adversarial mode, the actors are modified to perform adversarial to each other. In the fuzzy mode, noise is injected into the scenario (e.g., to replicate signal processing noise and other types of noise). Other modes may exist without departing from the scope of the system.

The simulator (200) includes the controller (212) that includes functionality to configure the various components of the simulator (200) according to the selected mode and phase. Namely, the controller (212) may modify the configuration of each of the components of the simulator based on configuration parameters of the simulator (200). Such components include the evaluator (210), the simulated environment (204), an autonomous system model (216), sensor simulation models (214), asset models (217), actor models (218), latency models (220), and a training data generator (222).

The autonomous system model (216) is a detailed model of the autonomous system in which the virtual driver will execute. The autonomous system model (216) includes model, geometry, physical parameters (e.g., mass distribution, points of significance), engine parameters, sensor locations and type, firing pattern of the sensors, information about the hardware on which the virtual driver executes (e.g., processor power, amount of memory, and other hardware information), and other information about the autonomous system. The various parameters of the autonomous system model may be configurable by the user or another system.

For example, if the autonomous system is a motor vehicle, the modeling and dynamics may include the type of vehicle (e.g., car, truck), make and model, geometry, physical parameters such as the mass distribution, axle positions, type and performance of engine, etc. The vehicle model may also include information about the sensors on the vehicle (e.g., camera, LiDAR, etc.), the sensors' relative firing synchronization pattern, and the sensors' calibrated extrinsics (e.g., position and orientation), and intrinsics (e.g., focal length). The vehicle model also defines the onboard computer hardware, sensor drivers, controllers, and the autonomy software release under test.

The autonomous system model includes an autonomous system dynamic model. The autonomous system dynamic model is used for dynamics simulation that takes the actuation actions of the virtual driver (e.g., steering angle, desired acceleration) and enacts the actuation actions on the autonomous system in the simulated environment to update the simulated environment and the state of the autonomous system. To update the state, a kinematic motion model may be used, or a dynamics motion model that accounts for the forces applied to the vehicle may be used to determine the state. Within the simulator, with access to real log scenarios with ground truth actuations and vehicle states at each time step, embodiments may also optimize analytical vehicle model parameters or learn parameters of a neural network that infers the new state of the autonomous system given the virtual driver outputs.

In one or more embodiments, the sensor simulation models (214) models, in the simulated environment, active and passive sensor inputs. Passive sensor inputs capture the visual appearance of the simulated environment including stationary and nonstationary simulated objects from the perspective of one or more cameras based on the simulated position of the camera(s) within the simulated environment. Examples of passive sensor inputs include inertial measurement unit (IMU) and thermal. Active sensor inputs are inputs to the virtual driver of the autonomous system from the active sensors, such as LiDAR, RADAR, global positioning system (GPS), ultrasound, etc. Namely, the active sensor inputs include the measurements taken by the sensors, the measurements being simulated based on the simulated environment based on the simulated position of the sensor(s) within the simulated environment. By way of an example, the active sensor measurements may be measurements that a LiDAR sensor would make of the simulated environment over time and in relation to the movement of the autonomous system.

The sensor simulation models (214) are configured to simulate the sensor observations of the surrounding scene in the simulated environment (204) at each time step according to the sensor configuration on the vehicle platform. When the simulated environment directly represents the real world environment, without modification, the sensor output may be directly fed into the virtual driver. For light-based sensors, the sensor model simulates light as rays that interact with objects in the scene to generate the sensor data. Depending on the asset representation (e.g., of stationary and nonstationary objects), embodiments may use graphics-based rendering for assets with textured meshes, neural rendering, or a combination of multiple rendering schemes. Leveraging multiple rendering schemes enables customizable world building with improved realism. Because assets are compositional in 3D and support a standard interface of render commands, different asset representations may be composed in a seamless manner to generate the final sensor data. Additionally, for scenarios that replay what happened in a real world and use the same autonomous system as in the real world, the original sensor observations may be replayed at each time step.

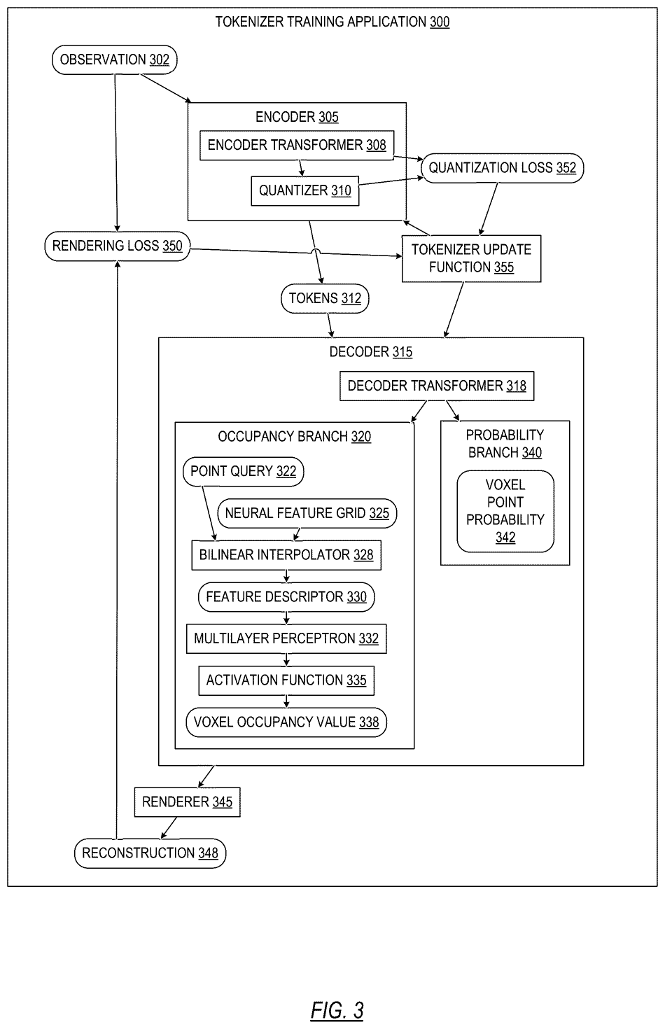

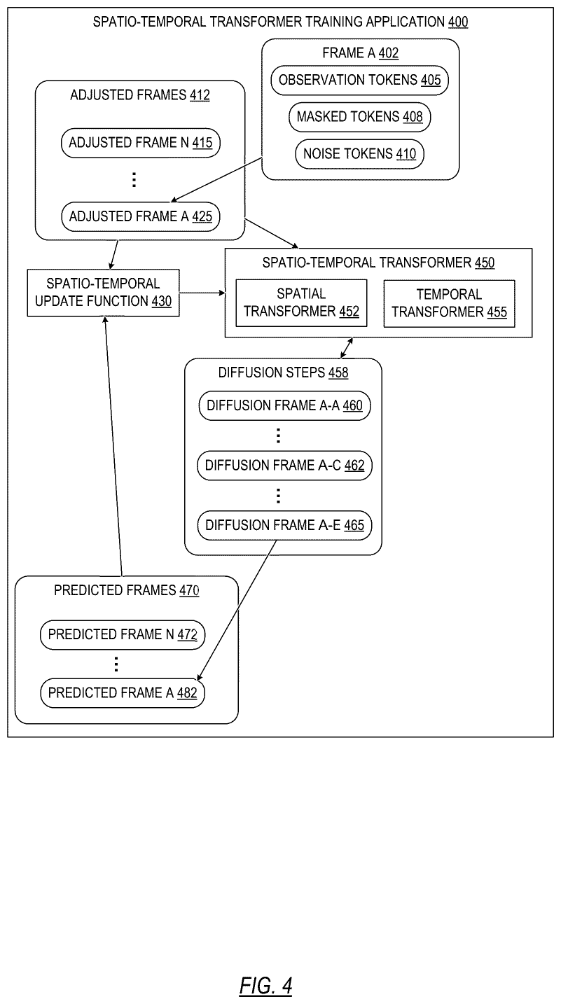

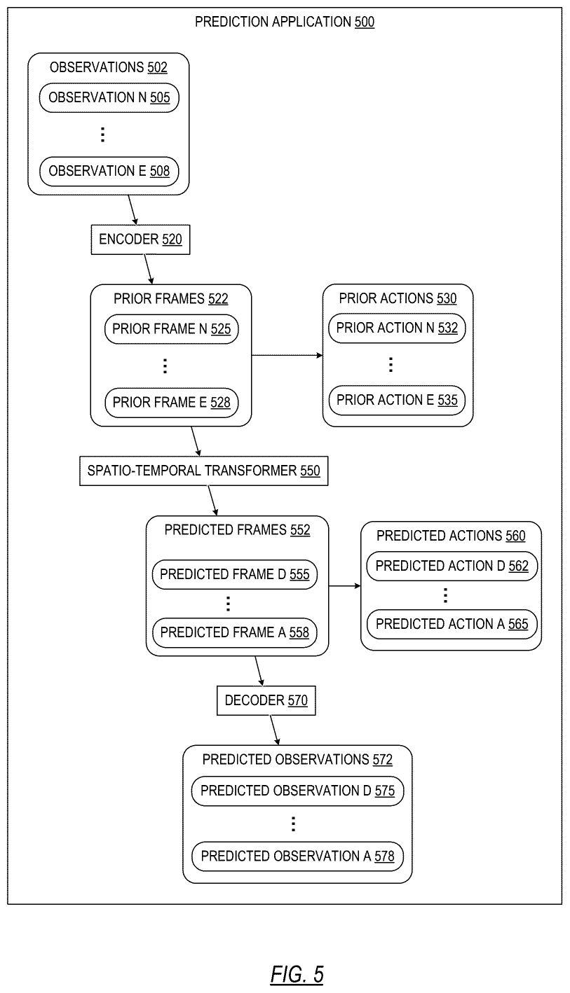

Additionally, the sensor simulation models (214) may deconstruct observations from sensors into frames of tokens. A frame may represent an observation and a token within the frame may be a feature vector that identifies features within a part of the frame. For a LiDAR sensor, the frame may be from a “bird's eye view”, i.e., above the autonomous vehicle and each token may correspond to a group of contiguous voxels within a volume that is a part of the total volume of the frame. To generate frames and tokens from observations, a training application (further described with FIG. 3) may be used to train encoder and decoder models that encode observations to frames of tokens and decode frames of tokens to observations. To predict future frames (and observations) another training application (further described with FIG. 4) may train a spatio-temporal transformer that uses diffusion to generate predictions of frames. The predicted frames may be decoded to predicted observations. The predictions, frames, tokens, observations, etc., may be used by other models of the simulator (200).

Asset models (217) include multiple models, each model modeling a particular type of individual asset from the real world. The assets may include inanimate objects such as construction barriers, traffic signs, parked cars, and background (e.g., vegetation or sky). Each of the entities in a scenario may correspond to an individual asset. As such, an asset model, or instance of a type of asset model, may exist for each of the entities or assets in the scenario. The assets can be composed together to form the three dimensional simulated environment. An asset model provides all the information needed by the simulator to simulate the asset. The asset model provides the information used by the simulator to represent and simulate the asset in the simulated environment. For example, an asset model may include geometry and bounding volume, the asset's interaction with light at various wavelengths of interest (e.g., visible for camera, infrared for LiDAR, microwave for RADAR), animation information describing deformation (e.g., rigging) or lighting changes (e.g., turn signals), material information such as friction for different surfaces, and metadata such as the asset's semantic class and key points of interest. Certain components of the asset may have different instantiations. For example, similar to rendering engines, an asset geometry may be defined in many ways, such as a mesh, voxels, point clouds, an analytical signed distance function, or neural network. Asset models may be created either by artists, or reconstructed from real world sensor data, or optimized by an algorithm to be adversarial.

Closely related to, and possibly considered part of the set of asset models (217), are actor models (218). An actor model represents an actor in a scenario. An actor is a sentient being that has an independent decision making process. Namely, in a real world, the actor may be an animate being (e.g., person or animal) that makes a decision based on an environment. The actor makes active movement rather than, or in addition to, passive movement. An actor model, or an instance of an actor model may exist for each actor in a scenario. The actor model is a model of the actor. If the actor is in a mode of transportation, then the actor model includes the mode of transportation in which the actor is located. For example, actor models may represent pedestrians, children, vehicles being driven by drivers, pets, bicycles, and other types of actors.

The actor model leverages the scenario specification and assets to control all actors in the scene and their actions at each time step. The actor's behavior is modeled in a region of interest centered around the autonomous system. Depending on the scenario specification, the actor simulation will control the actors in the simulation to achieve the desired behavior. Actors can be controlled in various ways. One option is to leverage heuristic actor models, such as an intelligent-driver model (IDM) that may try to maintain a certain relative distance or time-to-collision (TTC) from a lead actor or heuristic-derived lane-change actor models. Another is to directly replay actor trajectories from a real log, or to control the actor(s) with a data-driven traffic model. Through the configurable design, embodiments may mix and match different subsets of actors to be controlled by different behavior models. For example, far-away actors that initially may not interact with the autonomous system and can follow a real log trajectory, but when near the vicinity of the autonomous system may switch to a data-driven actor model. In another example, actors may be controlled by a heuristic or data-driven actor model that still conforms to the high-level route in a real log. This mixed reality simulation provides control and realism.

Further, actor models may be configured to be in cooperative or adversarial mode. In cooperative mode, the actor model models actors to act rationally in response to the state of the simulated environment. In adversarial mode, the actor model may model actors acting irrationally, such as exhibiting road rage and bad driving.

The latency model (220) represents timing latency that occurs when the autonomous system is in the real world environment. Several sources of timing latency may exist. For example, a latency may exist from the time that an event occurs to the sensors detecting the sensor information from the event and sending the sensor information to the virtual driver. Another latency may exist based on the difference between the computing hardware executing the virtual driver in the simulated environment as compared to the computing hardware of the virtual driver. Further, another timing latency may exist between the time that the virtual driver transmits an actuation signal to the autonomous system changing (e.g., direction or speed) based on the actuation signal. The latency model (220) models the various sources of timing latency.

Stated another way, in the real world, safety-critical decisions in the real world may involve fractions of a second affecting response time. The latency model simulates the exact timings and latency of different components of the onboard system. To enable a scalable evaluation without a strict requirement on exact hardware, the latencies and timings of the different components of autonomous system and sensor modules are modeled while running on different computer hardware. The latency model may replay latencies recorded from previously collected real world data or have a data-driven neural network that infers latencies at each time step to match the hardware in loop simulation setup.

The training data generator (222) is configured to generate training data. For example, the training data generator (222) may modify real world scenarios to create new scenarios. The modification of real world scenarios is referred to as mixed reality. For example, mixed reality simulation may involve adding in new actors with novel behaviors, changing the behavior of one or more of the actors from the real world, and modifying the sensor data in that region while keeping the remainder of the sensor data the same as the original log. In some cases, the training data generator (222) converts a benign scenario into a safety-critical scenario.

The simulator (200) is connected to a data repository (205). The data repository (205) is any type of storage unit or device that is configured to store data. The data repository (205) includes data gathered from the real world. For example, the data gathered from the real world includes real actor trajectories (226), real sensor data (228), real trajectory of the system capturing the real world (230), and real latencies (232). Each of the real actor trajectories (226), real sensor data (228), real trajectory of the system capturing the real world (230), and real latencies (232) is data captured by or calculated directly from one or more sensors from the real world (e.g., in a real world log). In other words, the data gathered from the real world are actual events that happened in real life. For example, in the case that the autonomous system is a vehicle, the real world data may be captured by a vehicle driving in the real world with sensor equipment.

Further, the data repository (205) includes functionality to store one or more scenario specifications (240). A scenario specification (240) specifies a scenario and evaluation setting for testing or training the autonomous system. For example, the scenario specification (240) may describe the initial state of the scene, such as the current state of the autonomous system (e.g., the full 6D pose, velocity, and acceleration), the map information specifying the road layout, and the scene layout specifying the initial state of all the dynamic actors and objects in the scenario. The scenario specification may also include dynamic actor information describing how the dynamic actors in the scenario should evolve over time, which are inputs to the actor models. The dynamic actor information may include route information for the actors, desired behaviors, or aggressiveness. The scenario specification (240) may be specified by a user, programmatically generated using a domain specification language (DSL), procedurally generated with heuristics from a data-driven algorithm, or adversarial. The scenario specification (240) can also be conditioned on data collected from a real world log, such as taking place on a specific real world map or having a subset of actors defined by their original locations and trajectories.

The interfaces between virtual driver and the simulator may match the interfaces between the virtual driver and the autonomous system in the real world. For example, the sensor simulation model (214) and the virtual driver matches the virtual driver interacting with the sensors in the real world. The virtual driver is the actual autonomy software that executes on the autonomous system. The simulated sensor data that is output by the sensor simulation model (214) may be in or converted to the exact message format that the virtual driver takes as input as if the virtual driver were in the real world, and the virtual driver can then run as a black box virtual driver with the simulated latencies incorporated for components that run sequentially. The virtual driver then outputs the exact same control representation that it uses to interface with the low-level controller on the real autonomous system. The autonomous system model (216) will then update the state of the autonomous system in the simulated environment. Thus, the various simulation models of the simulator (200) run in parallel asynchronously at their own frequencies to match the real world setting.

Turning to FIG. 3, the tokenizer training application (300) is a collection of programs executing on a computing system. The tokenizer training application (300) trains the machine learning models used to encode tokens from observations (e.g., the observation (302)) and to decode and reconstruct observations from tokens. The tokenizer training application (300) includes the encoder (305) and the decoder (315).

The observation (302) is a collection of sensor data. The observation (302) may be received from one or more sensors of an autonomous system. The observation (302) is the state of the geographic region at a particular point in time as captured by the sensors of the autonomous system. The sensors may perform one or more scans of the sensing region for the observation, whereby each of the scans are related to the same point in time (i.e., deemed concurrent). Data captured for the single point in time may be referred to as a frame.

The encoder (305) is a collection of programs operating as a machine learning model to process the observation (302) to generate the tokens (312). The encoder (305) may operate as a vector quantized variational autoencoder (VQVAE) to generate the tokens (312) from the observation (302). The encoder (305) includes the encoder transformer (308) and the quantizer (310).

The encoder transformer (308) is a component of the tokenizer training application (300), responsible for processing the observation (302), and generating meaningful features that will be quantized into the tokens (312) by the quantizer (310). The encoder transformer (308) may be a neural network that maps the input data to a latent space that is a lower dimensional representation of the input data. The encoder transformer (308) may utilize attention layers to analyze the input data, weighing the importance of different features and their interactions to produce representation.

The encoder transformer (308) (as well as any of the other transformers used by systems of the disclosure, including the decoder transformer (318) and the spatio-temporal transformer (450)) may include a Swin transformer. A Swin transformer utilizes a “shift window” to create separate representations for different parts of an input space to be separately processed. A Swin transformer may be more memory-efficient than a standard transformer due to the ability to process local information (e.g., a subset of tokens from a frame) without having to store each of the values for each token of a frame in memory at once.

The quantizer (310) is a component of the tokenizer training application (300) used in conjunction with the encoder transformer (308) to generate the tokens (312) from the observation (302). The quantizer (310) maps the features generated by the encoder transformer (308) into discrete values, effectively discretizing the continuous input space. Discrete values are countable and distinct entities, such as integers (1, 2, 3, . . . ), whereas continuous values can take any value within a given range or interval, including fractions and decimals (e.g., 0.5, 3.14, . . . ). Quantization, with the quantizer (310), allows for efficient encoding of complex data and facilitates parallel processing. By quantizing the input features generated from the observation (302), the quantizer (310) enables the model to operate on a more manageable and computationally efficient representation of the observation.

The tokens (312) are discrete values generated from the observation (302) by the quantizer (310), allowing for efficient encoding of complex data. These tokens represent the encoded representation of the observation (302) in a more manageable and computationally efficient format. The tokens (312) can be used as input to various machine learning models or other algorithms within the tokenizer training application (300). By discretizing the continuous input space, the quantizer (310) enables parallel processing and facilitates faster computations.

The decoder (315) decodes the tokens (312) back into data that may be rendered into an observation. During training, the rendering generates a reconstruction (the reconstruction (348)) of the observation (302). The decoder (315) may include the decoder transformer (318) and utilize multiple branches, including the occupancy branch (320) and the probability branch (340). The output of the decoder (315) may be input to the renderer (345).

The decoder transformer (318) is a component of the tokenizer training application (300), that processes the tokens (312) to recover voxel information from the tokens (312). The voxel information may be a scaled version of the space of the observation (302). The decoder transformer (318) may be a neural network using attention layers to map the input data to a higher dimensional space. The attention layers of the decoder transformer (318) analyze the input data, weighing the importance of different features and the different features' interactions to produce representations. Output from the decoder transformer (318) may be input to the occupancy branch (320) and the probability branch (340).

The occupancy branch (320) processes the output of the decoder transformer (318) to generate the voxel occupancy value (338). The occupancy branch (320) may execute for each voxel of each token of a frame of tokens.

The point query (322) is a set of coordinates that identify a point (e.g., a location) within a voxel. The point query (322) is input to the bilinear interpolator (328).

The neural feature grid (325) is a grid of features output from the decoder transformer (318). The neural feature grid (325) may represent a three-dimensional space with data for certain points within the three-dimensional space. Thus, each value in the neural feature grid has a corresponding location in the three-dimensional space. In one or more embodiments, the three-dimensional space is the geographic region around the autonomous system.

The bilinear interpolator (328) is a component used by the occupancy branch (320). The bilinear interpolator (328) interpolates information from the neural feature grid (325) to identify feature information for a point identified by the point query (322). The output of the bilinear interpolator (328) is the feature descriptor (330).

The feature descriptor (330) is an output of the bilinear interpolator (328). The feature descriptor (330) represents feature information for a point identified by the point query (322) within a voxel represented by one of the tokens (312).

The multilayer perceptron (332) is a neural network architecture used in the occupancy branch (320). The multilayer perceptron (332) takes the feature descriptor (330) as input and generates an intermediate representation of a voxel occupancy value before being processed with the activation function (335). The multilayer perceptron (332) may be composed of multiple layers of artificial neurons, each with a set of weights and biases that may be learned during training to increase the accuracy in predicting voxel occupancy values.

The activation function (335) may be a component of the multilayer perceptron (332) that is responsible for introducing non-linearity into the model to enabling the multilayer perceptron (332) to learn complex relationships between the input features and voxel occupancy values. The activation function (335) may be a sigmoid activation function, which maps outputs of the multilayer perceptron to values between 0 and 1. Mapping to the fixed range allows the model to produce a probability-like output for each voxel, indicating the likelihood that a voxel is occupied by an object in the reconstruction (348).

The voxel occupancy value (338) is an output of the multilayer perceptron (332), representing an intermediate representation of the occupancy status of a voxel before being processed with the activation function (335) to produce a probability-like output. The voxel occupancy value (338) may be interpreted as a likelihood that a voxel within the rendered reconstruction (348) is occupied by a real-world object. The voxel occupancy value (338) quantifies the spatial composition of a scene that includes the voxel.

The probability branch (340) processes the output of the decoder transformer (318) to generate the voxel point probability (342). The probability branch (340) may execute for each voxel of each token of a frame of tokens.

The voxel point probability (342) is a numerical value representing the likelihood of a specific point within a voxel being occupied by an object in the three-dimensional space. The voxel point probability (342) provides information about the spatial distribution and composition of objects that may be within an observation.

The renderer (345) is a component of the tokenizer training application (300) that processes output from the decoder (315), including the voxel occupancy value (338) and the voxel point probability (342), to form the reconstruction (348). For the points within the space of the reconstruction (348), the renderer (345) may combine the corresponding voxel occupancy values and voxel point probabilities to create the reconstruction (348), which should be similar (if not the same as) to the observation (302) during training.

The reconstruction (348) is a representation of sensor data measurements. The reconstruction (348) should be the same as the observation (302) but will have some loss after being decoded from the tokens (312) generated by the encoder (305). The reconstruction (348) may be rendered in various formats such as point cloud data or mesh, in correspondence with the type of sensor that generated the observation (302).

The rendering loss (350) measures the error between the observation (302) and the reconstruction (348). The error may be quantified with a loss function that compares values from the observation (302) with values from the reconstruction (348).

The quantization loss (352) measures the error between the output of the encoder transformer (308) and the output of the quantizer (310), i.e., the tokens (312). The quantization loss (352) arises from the fact that the quantizer (310) maps continuous values to the discrete values of the tokens (312), resulting in a reduction in precision and potentially leading to inaccuracies.

The tokenizer update function (355) processes the rendering loss (350) and quantization loss (352) to update the weights of the encoder (305) and decoder (315). The update process may iteratively adjust the parameters and weights of the encoder (305) and decoder (315) through backpropagation and stochastic gradient descent algorithms.

Turning to FIG. 4, the spatio-temporal transformer training application (400) is a collection of programs that train machine learning models, including the models of the spatio-temporal transformer (450). Where the tokenizer training application (300) trains the models that encode and decode tokens, the spatio-temporal transformer training application (400) trains the model that uses the tokens to predict future tokens, i.e., the spatio-temporal transformer (450). The spatio-temporal transformer training application (400) masks out tokens and injects noise into tokens to form the adjusted frames (412). For example, the frame A (402) may have originally included observation tokens without any masked tokens or noise tokens. The spatio-temporal transformer training application (400) may replace some of the initial observation tokens with the masked tokens (408) and the noise tokens (410).

The frame A (402) is processed to include the observation tokens (405), the masked tokens (408), and the noise tokens (410). The frame A (402) forms the adjusted frame A (425).

The observation tokens (405) include data from an observation generated with a sensor from an autonomous system of a vehicle. The observation tokens (405) are a subset of the initial observation tokens corresponding to the frame A (402) that are not replaced with masked tokens or noise tokens.

The masked tokens (408) do not include data from an observation generated with a sensor. As an example, each of the values within the masked tokens (408) may be set to a mask value, such as “0”.

The noise tokens (410) are tokens into which noise has been injected into the initial values from an observation. Different types of noise may be used.

The adjusted frames (412) are a collection that includes the adjusted frames N (415) through A (425) that are used as input for processing by the spatio-temporal transformer (450) to generate the predicted frames (470). The adjusted frames (412) are formed by replacing tokens from an initial observation with masked and noise tokens. Each of the adjusted frames (412) corresponds to a single point in time, allowing the spatio-temporal transformer to process multiple points in time simultaneously using the temporal transformer (455).

The spatio-temporal transformer (450) processes the adjusted frames (412) to generate predicted frames (470) utilizing the diffusion steps (458). The spatial transformer (452) and temporal transformer (455) are components of the spatio-temporal transformer (450), with the spatial transformer (452) processing tokens within a single frame at a specific point in time and the temporal transformer processing tokens across multiple frames over time.

The spatial transformer (452) is a component of the spatio-temporal transformer (450) that processes tokens within a single frame at a specific point in time and multiple points in space. The spatial transformer (452) utilizes attention layers to analyze the input data, weighing the importance of different features and their interactions to produce representations that capture spatial relationships between tokens.

The temporal transformer (455) is a component of the spatio-temporal transformer (450) that processes tokens across multiple frames corresponding to multiple points in time. The attention layers of the temporal transformer (455) process the input data to weigh the importance of different features and their interactions to produce representations that capture temporal relationships between tokens from a point or volume in space.

The diffusion steps (458) are intermediate steps that may generate each of the predicted frames (470). One step of the diffusion steps (458) generates one diffusion frame of the diffusion frames A-A (460) through A-E (465). Each step of the diffusion steps (458) may replace masked tokens and noise tokens.

As an example, a first step may process the adjusted frame A (425) with the spatio-temporal transformer (450) to generate the diffusion frame A-A (460). Some of the masked and noise tokens from the adjusted frame A (425) are replaced with tokens predicted by the spatio-temporal transformer (450) to form the diffusion frame A-A (460). The diffusion frame A-A (460) may then be input at the spatio-temporal transformer (450) generate one of the subsequent diffusion frames that has even fewer mask and noise tokens. The diffusion frame A-E (465) may correspond to a last step of the diffusion steps (458) and have no mask or noise tokens (being replaced with tokens predicted from the spatio-temporal transformer (450)).

The diffusion frame A-A (460) replaces some of the masked tokens (408) and noise tokens (410) with predictions from the spatio-temporal transformer. The diffusion frame A-A (460) may include a similar or greater number of masked tokens as compared to the subsequent diffusion frame A-C (462). The diffusion frame A-A (460) may also include a similar or greater number of noise tokens as compared to the subsequent diffusion frame A-C (462).

The diffusion frame A-C (462) has more masked tokens and noise tokens replaced with predictions from the spatio-temporal transformer (450). The diffusion frame A-C (462) includes a similar or greater number of masked tokens as compared to the subsequent diffusion frame A-E (465) and also includes a similar or greater number of noise tokens as compared to the subsequent diffusion frame A-E (465).

The diffusion frame A-E (465) may be generated from a last step of the diffusion steps (458) with each of the masked tokens and noise tokens being replaced with predictions from the spatio-temporal transformer (450). As a result, no more masked tokens and no more noise tokens are included in the diffusion frame A-E (465).

The predicted frames (470) are a collection of predicted frames that include the predicted frames N (472) through A (482). The predicted frames N (472) through A (482) correspond to the adjusted frames N (415) through A (425) with masked and noise tokens replaced by predictions from the spatial temporal transformer (450).

The spatio-temporal update function (430) calculates the error between frames of the predicted frames (470) and frames of the adjusted frames (412). The error is used to update the weights and parameters of the spatio-temporal transformer (450). The updates may be performed using backpropagation, gradient descent, etc.

Turning to FIG. 5, the prediction application (500) is a collection of programs that processes the observations (502) to generate the predicted observations (572). The prediction application (500) uses the encoder (520) and the decoder (570) (trained with the tokenizer training application (300)) along with the spatio-temporal transformer (550) (trained with the spatio-temporal transformer training application (400)) to generate the predicted observations (572).

The observations (502) are a collection of observations that includes sensor data from a sensor. The observations (502) include the observations N (505) through E (508), which may be taken at different points in time. The observation N (505) may be an initial observation in the set of observations (502) and the observation E (508) may be a last observation in the set of observations (502).

The encoder (520) processes the observations (502) to generate the prior frames (522). The encoder (520) may be the encoder (305) trained with the tokenizer application (300) of FIG. 3.

The prior frames (522) are outputs from the encoder (520) frame N (525) through E (528). The prior frames (522) may be used to generate the prior actions (530).

The prior actions (530) are a collection of actions including the actions N (532) through E (535). An action of the prior actions (530) may be a collection of data that identifies a pose of an actor (which may represent a vehicle) that generated the observations (502). The pose of an actor may identify the direction, heading, etc., of the vehicle.

The spatio-temporal transformer (550) processes the prior frames (522) to generate the predicted frames (552) using two or more diffusion steps. The spatio-temporal transformer (550) may be the spatio-temporal transformer (450) trained by the spatio-temporal transformer training application (400) of FIG. 4. The spatio-temporal transformer (550) may process each of the prior frames (522) to generate one of the predicted frames (552).

The predicted frames (552) are outputs from the spatial temporal transformer (550) and include the predicted frame D (555) through A (558). The predicted frames (552) correspond to a point in time in the future after the collection of the observations (502). The predicted frame D (555) may be the frame predicted to occur after the prior frame E (528).

The predicted actions (560) are a collection of predicted actions generated from the predicted frames (552). The predicted actions (560) may be poses of actors that are used to identify vehicle control information (acceleration, braking, steering, etc.). The predicted actions (560) include the predicted actions D (562) through A (565). The predicted action D (562) may be determined after the predicted frame D (555) generated. The predicted action A (565) may be determined after the predicted frame A (558) is generated.

The decoder (570) processes the predicted frames (552) to generate the predicted observations (572). The decoder (570) may be the decoder (315) trained by the tokenizer training application (300) of FIG. 3.

The predicted observations (572) are generated from the predicted frames (552) by the decoder (570). The predicted observations (572) include the predicted observations D (575) through A (578). The predicted observation D (575) is the observation predicted to occur after the observation E (508) at the next time step.

Although described within the context of multiple applications that may execute on multiple computing systems, aspects of the disclosure may be practiced with a single computing system and application. For example, a monolithic application may operate on a computing system to perform the same functions as one or more of the applications executed by the autonomous system (116) and the computing system (1100).

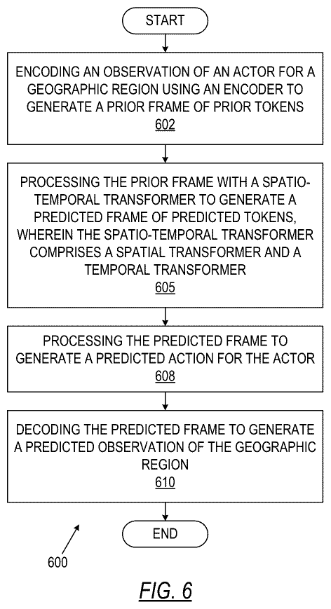

FIG. 6 shows a flowchart of a method for determining when to retrain raster digitization components. The method of FIG. 6 may be implemented using the systems and components of FIG. 1 through FIG. 5 and FIG. 11A and FIG. 11B. One or more of the steps of the method may be performed on, or received at, one or more computer processors. In an embodiment, a system may include at least one processor and an application that, when executing on the at least one processor, performs the method. In an embodiment, a non-transitory computer readable medium may include instructions that, when executed by one or more processors, perform the method. The outputs from various components (including models, functions, procedures, programs, processors, etc.) from performing the method may be generated by applying a transformation to inputs using the components to create the outputs without using mental processes or human activities.

Block (602) includes encoding an observation of an actor for a geographic region using an encoder to generate a prior frame of prior tokens. Encoding the observation may utilize multiple machine learning models and architectures within the encoder to generate the prior frame of prior tokens. To encode the observation, data within the observation may be rearranged and rescaled. For example, a point cloud that forms an observation from a LiDAR sensor may be filtered and transformed into a 2D grid representation of the BEV space by projecting each point onto a virtual x-y plane perpendicular to the vehicle z-axis. Each cell in the grid represents a specific location in the BEV space, such as a pixel on an image. The size and resolution of the BEV grid may be determined by the field of view (FOV) of the LiDAR sensor and scanning frequency. Next, each point within the BEV grid may be assigned a token based on the type of object represented by the token, such as an obstacle (e.g., car or pedestrian), empty space, or unknown. Various techniques may be used including ray casting, voxelization, machine learning-based methods, etc. The resulting BEV token grid is a frame of tokens that provides a compact representation of the environment surrounding a vehicle.

Encoding the observation may include processing the observation using an encoder transformer. The observation includes data output from a sensor. The encoder transformer is a machine learning model that may use an attention algorithms, layer normalization, residual connections, etc., to generate the tokens of a frame from an observation.

Encoding the observation may further include processing output from the encoder transformer using a quantizer to select the tokens from a codebook. The quantizer may operate to compute the vector distances between each input feature and the centroids of the codebook, which is a collection of discrete tokens representing learned latent representations. The closest centroid to the input feature (output from the encoder transformer) may be selected as a quantization index to form the token of a frame and map the continuous input space of the outputs of the encoder transformer into a discrete representation defined by the centroids in the codebook. These steps may be repeated for each of the outputs from the encoder transformer, and the resulting indices identified by the quantizer are used to select the corresponding centroids from the codebook to form the tokens of a frame to yield a discrete and compressed representation of the input data (e.g., the point cloud of an observation).

Block (605) includes processing the prior frame with a spatio-temporal transformer to generate a predicted frame of predicted tokens. The spatio-temporal transformer includes a spatial transformer and a temporal transformer. The spatio-temporal transformer processes the prior tokens from a set of prior frames by executing multiple transformer layers to capture both spatial and temporal relationships between tokens within each frame as well as across multiple frames over time. The prior tokens of a single prior frame at a specific point in time may be processed to generate a spatial output for one of the prior tokens of the prior frame. The prior tokens at the same location across multiple frames that correspond to multiple points in time may be processed to generate a temporal output for the prior token of the temporal set of prior tokens. The temporal transformer output may be combined with the spatial output to form a predicted token for the predicted frame. This process may be repeated for each prior token within a prior frame to generate a predicted frame of predicted tokens.

Processing the prior frame with a spatio-temporal transformer may include processing a spatial set of prior tokens from the prior frame with the spatial transformer to generate a spatial transformer output for a prior token of the spatial set of prior tokens. To process a spatial set of prior tokens from the prior frame, the spatial transformer first analyzes the input data, weighing the importance of different features and their interactions using attention layers to produce representations that capture spatial relationships between tokens. This is done by processing the tokens within each frame at a specific point in time, utilizing attention mechanisms to focus on relevant information and ignore irrelevant information. The spatial transformer then uses this analysis to generate a spatial output for one of the prior tokens of the spatial set of prior tokens, which captures the spatial relationships between the token and its neighboring tokens.

The attention mechanism generates a set of queries, keys, and values from the input tokens. The queries are used to compute weighted sums of the value vectors, which are then combined to produce a single output vector that captures the context surrounding each token. The output vector may be generated by computing the dot product between the query and key vectors, followed by a softmax function to normalize the weights, allowing the spatial transformer to weigh the importance of different features and their interactions, effectively producing representations that capture the spatial relationships between tokens.

Processing the prior frame with a spatio-temporal transformer may further include processing a temporal set of prior tokens from a set of prior frames, including the prior frame, with the temporal transformer to generate a temporal transformer output for the prior token of the temporal set of prior tokens. The prior token is one of the spatial set of prior tokens and is one of the temporal set of prior tokens.

The temporal transformer processes the temporal set of prior tokens from the prior frame by analyzing the input data, weighing the importance of different features and their interactions using attention layers to produce representations that capture temporal relationships between tokens across multiple frames over time. The attention mechanism generates a set of queries, keys, and values from the input tokens, which are then used to compute weighted sums of the value vectors (i.e., values). The output vector captures the context surrounding each token by computing the dot product between the query and key vectors (i.e., the queries and keys) followed by a softmax function to normalize the weights. The analysis is performed for each prior token within the temporal set of prior tokens, resulting in a temporal transformer output that captures the temporal relationships between the prior tokens from multiple frames.

Processing the prior frame with a spatio-temporal transformer may include executing a diffusion process using the spatio-temporal transformer to generate a sequence of diffusion frames. The sequence of diffusion frames includes one or more of a previous diffusion frame, a subsequent diffusion frame, and the predicted frame. The previous diffusion frame includes more masked tokens than the subsequent diffusion frame. The predicted frame includes zero masked tokens.

The execution of the diffusion process using the spatio-temporal transformer to generate a sequence of diffusion frames may involve multiple steps. A previous diffusion frame (or an initial adjusted frame at the first step of the diffusion process) may be processed with the spatio-temporal transformer to generate a subsequent diffusion frame. Multiple diffusion frames may be iteratively generated, each having fewer masked and noise tokens, until a predicted frame is generated, which includes zero masked or noise tokens. In each step of the diffusion process, some of the masked and noise tokens from the adjusted frame are replaced with tokens predicted by the spatio-temporal transformer to form the subsequent diffusion frame. The diffusion frames can be considered as intermediate steps in the diffusion process, where the masked tokens and noise tokens are gradually replaced with predictions from the spatio-temporal transformer until a final predicted frame is generated that has no masked or noise tokens.

Block (608) includes processing the predicted frame to generate a predicted action for the actor. The predicted frame may be processed using a pose model to generate an actor pose (also referred to as an ego vehicle pose) that identifies a pose of the actor that generated the observation. The pose may be the predicted action from which a set of actions may be determined based on its predicted position, orientation, velocity, etc., of the vehicle identified in the predicted action. The set of vehicle actions with the highest probability or confidence may be selected to be performed by the autonomous system. Multiple actions may be identified to be executed (e.g., breaking and steering), in which case a decision-making algorithm may be employed to select the most appropriate action based on factors such as safety and efficiency. The set of vehicle actions generated from the predicted action may be transmitted to the control system for execution for navigation through the environment.

Processing the predicted frame to generate the predicted action may include processing the predicted frame using a pose model to generate an actor pose identifying a pose of an actor that generated the observation. The pose model may use machine learning layers (perceptron layers, attention layers, activation layers, etc.) to extract the pose from the predicted frame.

Block (610) includes decoding the predicted frame to generate a predicted observation of the geographic region. The process of generating a predicted observation by decoding a predicted frame involves processing the predicted frame using a decoder transformer that maps input data to a higher dimensional space through attention layers that analyze and weigh the importance of different features and their interactions.

Decoding the predicted frame may include processing the predicted frame using a decoder transformer including an occupancy branch and a probability branch. The occupancy branch and the probability branch provide different types of outputs that are combined to improve the accuracy of the decoder.

Decoding the predicted frame may further include processing the predicted frame using an occupancy branch to generate a voxel occupancy value. The occupancy branch may process the output of a decoder transformer using a point query and neural feature grid that are input to a bilinear interpolator to generate a feature descriptor. The feature descriptor may be processed with a multilayer perceptron and then an activation function to produce a voxel occupancy value that identifies whether a voxel represented by a predicted token in the predicted frame is occupied.

Decoding the predicted frame may further include processing the predicted frame using a probability branch to generate a voxel point probability. The probability branch processes the output from the decoder transformer to generate voxel point probabilities. Voxel point probabilities may be generated for one or more of the voxels represented by the predicted tokens in the predicted frame.

Decoding the predicted frame may further include processing the voxel occupancy value and the voxel point probability using a renderer to construct a predicted observation from the predicted frame. Multiple types of data (voxel occupancy values, voxel point probabilities, etc.) may be generated for each voxel that may be represented in an observation (or reconstruction of an observation). The multiple types of data may be combined and transformed (scaled, rotated, interpolated, etc.) to generate data in a space that corresponds to the space of the original input data, i.e., of an observation from a sensor.

The process (600) may further include training the spatio-temporal transformer. To train a spatio-temporal transformer training data may be generated that includes frames generated from historical observations. The frames may be processed to mask certain tokens and inject noise into other tokens to generate a set of adjusted frames. The adjusted frames may be input to the spatio-temporal transformer that uses diffusion steps to then generate predicted frames. The predicted frames are compared to the frames, i.e., the “original” or “ground truth” frames prior to the adjustments of adding masks and noise, to identify the error between the tokens of the predicted frames and the tokens of the original frames. The error between tokens is used to update the weights and parameters of the spatio-temporal transformer.

Training the spatio-temporal transformer may include masking a first set of initial tokens within each training frame of a sequence of training frames to form a set of masked tokens within the sequence of training frames. The masking may be performed by selecting a random set of tokens and setting the values in the selected tokens to a mask value (e.g., to “0”).

Training the spatio-temporal transformer may further include injecting noise into a second set of initial tokens within each training frame of a sequence of training frames to form a proxy of noise tokens within the sequence of training frames. The injection of noise may be performed by selecting a random set of tokens and combining noise values with the values of the tokens. Types of noise may include uniform noise, Gaussian noise, Gerber noise, Poisson noise, etc.

Training the spatio-temporal transformer may further include executing the spatio-temporal transformer using the sequence of training frames including the set of masked tokens and the set of noise tokens to generate a set of recovered tokens corresponding to the first set of initial tokens and to the second set of initial tokens within the sequence of training frames. The recovered tokens are the predicted tokens generated by the spatio-temporal transformer in response to the adjusted tokens from the adjusted frame there was input to the spatio-temporal transformer.

Training the spatio-temporal transformer may further include executing a loss function using cross entropy to update weights of the spatio-temporal transformer to reduce error between the set of recovery tokens with the first set of initial tokens and the second set of initial tokens for subsequent execution of the spatio-temporal transformer. The cross-entropy loss measures the difference between the probability distribution of the recovered tokens and the probability distribution of the original tokens. The errors identified from the cross-entropy loss are backpropagated through the spatio-temporal transformer to compute the gradients of the loss with respect to each weight and used to update the weights.

The process (600) may further include training the spatio-temporal transformer with a mixture of objectives. Using different objectives during training improves the training of the spatio-temporal transformer for more accurate predictions. The different objectives may include “condition on the past, denoise the future”, “denoise the past and the future jointly”, and “denoise each frame individually, regardless of past or future” in which “denoising” may remove noise and may also include demasking the tokens of frames. With “condition on the past, denoise the future”, information past (or “previous”) frames of a sequence of frames may be used to denoise future frames, but information from future frames may not be used to denoise past frames. With “denoise the past and the future jointly”, information from past and future frames may be used to denoise both past and future frames. With “denoise each frame individually, regardless of past or future”, a single (or “current”) frame is denoised without using information from past or future frames. Different percentages of training executions may be used for the different objectives. As an example, a first objective may include 50% of training executions, objective may include 40% of training executions, and a third objective may include 10% of training executions. Percentages may be utilized.

Training the spatio-temporal transformer with a mixture of objectives may include executing the spatio-temporal transformer using causal masking of the temporal transformer to recover subsequent frames from previous frames for a first percentage of training executions. Recovering subsequent frames from previous frames may implement the objective of “condition on the past, denoise the future”.

Training the spatio-temporal transformer with a mixture of objectives may further include executing the spatio-temporal transformer using causal masking of the temporal transformer to jointly recover subsequent frames and previous frames for a second percentage of training executions. Jointly recovering subsequent and previous frames may implement the objective of “denoise the past and the future jointly”.

Training the spatio-temporal transformer with a mixture of objectives may further include executing the spatio-temporal transformer using an identity matrix with the temporal transformer to recover each training frame individually for a third percentage of training executions. Using the identity matrix with the temporal transformer may implement the objective of “denoise each frame individually, regardless of past or future”. The first percentage of training executions may be greater than the second percentage of training executions. The second percentage of training executions may be greater than the third percentage of training executions.

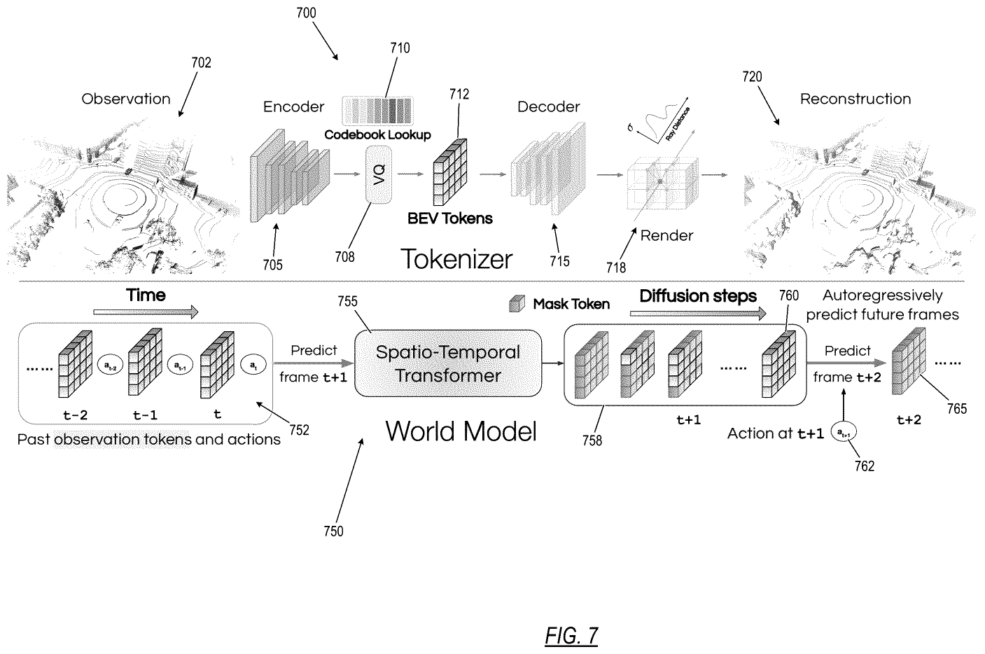

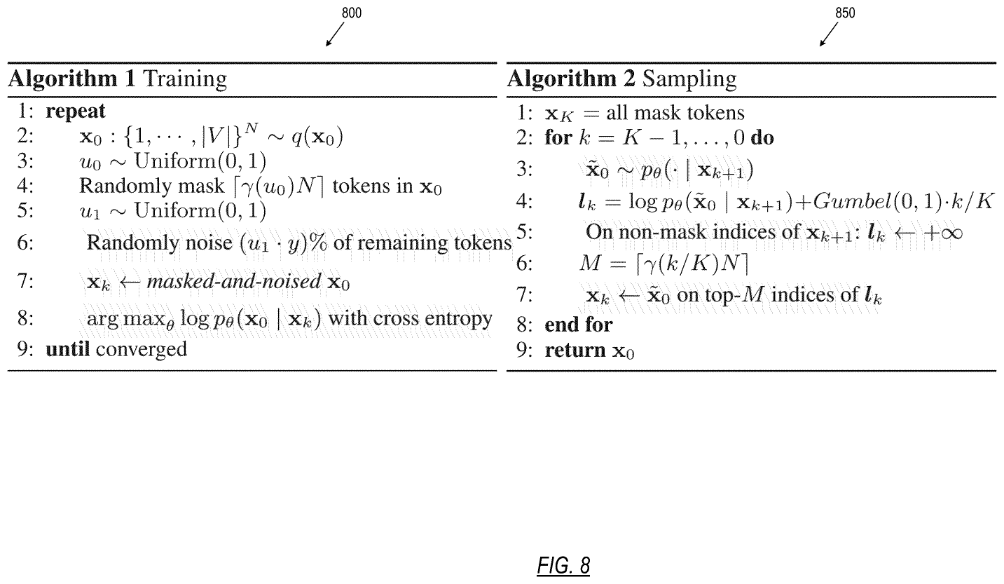

FIG. 7 through FIG. 10 depict examples of system and methods implementing the disclosure. FIG. 7 illustrates the processes of tokenization and prediction. FIG. 8 illustrates algorithms that may be used for training and sampling. FIG. 9 illustrates different objectives for training. FIG. 10 illustrates predicted observations.

Turning to FIG. 7, the process (700) illustrates encoding and decoding to tokenize observations (i.e., encode) and generate reconstructions of observations (or predicted observations). The observation (702) is input to the encoder (705), which processes the observation to generate a token having continuous values. The output from the encoder (705) is input to the quantizer (708), which uses the codebook (710) to look up a discrete value for the output from the encoder (705). The output of the quantizer (708) is the frame (712) of tokens, which are bird's eye view (BEV) tokens from the perspective of the vehicle that captured the observation (702).

A frame, e.g., the frame (712), is processed by the decoder (715). The output of the decoder (715) is processed by the renderer (718) to generate the reconstruction (720). The reconstruction (720) may be a reconstruction of the observation (702).

The process (750) illustrates generating predicted frames (of predicted tokens) and generating predicted actions. The sequence (752) of past tokens and actions (e.g., for time steps t, t−1, t−2, etc.) is processed with the spatio-temporal transformer (755). With the spatio-temporal transformer (750) sequence (752), multiple diffusion frames are generated with the diffusion steps (758). The predicted frame (760), which is the last frame generated with the diffusion steps (758), is the predicted frame for time step t+1. After generating the predicted frame (760), the predicted action (762) is generated. The subsequent frame (765) (for time step t+2) may be generated by updating the sequence (752) with the predicted frame (760) and the predicted action (762).

Put another way, given a sequence of agent experience (o⁽¹⁾, a . . . o^{(T-1)}, a^{(T-1)}, o^{(T)}) where o is an observation (e.g., the observation (702)) and a is an action (e.g., one of the actions from the sequence (752)), a world model p_{θ} may be learned that predicts a subsequent observation given the past observations and actions. The subsequent observation is decoded from a frame of tokens for the subsequent observation. The past observations are encoded as frames of tokens to form a sequence of observation tokens and action (e.g., the sequence (752)). Each observation o^{(T)} may be tokenized into a vocabulary V (a learned codebook in VQVAE), obtaining x^{(t)}∈{0, . . . , |V|−1}^{N}, where N is the number of tokens in each observation. The tokenized observation t is denoted x^{(t)} as the learning objective is:

$${argmax}_{θ} {\sum }_{t} log p θ ( {x}^{( t )} \vert {x}^{( 1 )} , {a}^{( 1 )} , ⋯ , {x}^{( x - 1 )} , {a}^{( t - 1 )} ) \qquad Eq . 1$$

The world model is a discrete diffusion model that may perform conditional generation given past observations and actions. To denote the diffusion process, the tokenized observation t under forward diffusion step k is denoted as xₖ^{(t)}. k=0 is the original data distribution. To predict an observation at timestep t, the world model starts from fully masked x_{K}^{(t)} (i.e., each value of each token is set to a mask value), and iteratively denoises it into x₀^{(t)}. The number of denoising steps K may be selected at inference (5, 10, 20, etc., steps). In the autonomous driving setting, the observations {o^{(t)}}ₜ are point clouds from a LiDAR sensor, and the actions {a^{(t)}}ₜ are SE(3) (special Euclidean group in 3 dimensions) ego poses.

For tokenization, embodiments of the disclosure include improvements to a VQVAE (vector quantized variational autoencoder) model to tokenize the 3D world represented by point clouds of the observations. The model (which may include the encoder (705), the quantizer (708), and the decoder (715)) learns latent codes in a “bird's-eye view” (BEV) perspective and is trained to reconstruct point clouds via differentiable depth rendering.

The encoder (705) may use point cloud based object detection components to perform several steps. First, point-wise features of each voxel are aggregated with a PointNet model. Next, voxel-wise features are aggregated into BEV pillars. Next, a Swin transformer is used to obtain a feature map that may be downsampled (e.g., 8× downsampled) from the initial voxel size in BEV perspective of the observation. The output of the encoder (705), denoted as z=E(0), goes through a vector quantization layer (the quantizer (708)) to produce an output denoted as \hat{z}.

An improvement to the tokenization process (700) is included in the decoder (715), which produces two branches of outputs after one or more Swin transformer layers. The first branch (i.e., the occupancy branch) uses an implicit representation so that occupancy values may be queried at continuous coordinates. To query (x, y, z), a bilinear interpolation on a 3D neural feature grid (NFG) is executed and outputted by the decoder to obtain a feature descriptor. The feature descriptor goes through a multilayer perceptron (MLP) and sigmoid activation to arrive at an occupancy value, a, in the range [0, 1]. Given a ray r(h)=p+hd, the expected depth may be calculated via differentiable depth rendering on Nᵣ sampled points {(xᵢ, yᵢ, zᵢ)}ᵢ₌₁^{N}^{ᵣ} along the ray r, in accordance with the equations below.

$$D ( r , \hat{z} ) = {\sum }_{i = 1}^{{N}_{r}} {w}_{i} {h}_{i} \qquad Eq . 2$$

$${w}_{i} = {α}_{i} {\prod }_{j = 1}^{i - 1} ( 1 - {α}_{j} ) \qquad Eq . 3$$

$${α}_{i} = σ ( MLP ( interp ( NFG ( \hat{z} ) , ( {x}_{i} , {y}_{i} , {z}_{i} ) ) ) ) \qquad Eq . 4$$

The second branch (i.e., the probability branch) learns a coarse reconstruction of the point clouds by predicting whether a voxel has points in the inputs to the voxel. The binary probability is denoted as v. During inference, the second branch is used for spatial skipping to speed up point sampling in rendering.

The loss function for the tokenizer (used to update the weights for the machine learning model layers of the encoder, the quantizer, and the decoder) is a combination of the vector quantization loss [symbol] _{vq} and the rendering loss [symbol] _{render}. The vector quantization loss learns the codebook and regularizes the latents and may use the equation below.

$${ℒ}_{vq} = {λ}_{1} {‖ sg [ E ( o ) ] - \hat{z} ‖}_{2}^{2} + {λ}_{2} {‖ sg [ \hat{z} ] - E ( o ) ‖}_{2}^{2} \qquad Eq . 5$$

In the rendering loss, supervision may be applied on both branches: the depth rendering branch has an L1 loss on depth with an additional term that encourages wᵢ to concentrate within c of the surface. The spatial skipping branch optimizes binary cross entropy. The tokenizer is trained end-to-end to reconstruct the observation and may use the equation below.

$${ℒ}_{render} = {𝔼}_{r} [ {‖ D ( r , \hat{z} ) - {D}_{gt} ‖}_{1} + {\sum }_{i} ( \vert {h}_{i} - {D}_{gt} \vert > ϵ ) {‖ {w}_{i} ‖}_{2} ] + BCE ( v , {v}_{gt} ) \qquad Eq . 6$$

After pretraining a tokenizer, subsequent generative models deal with discrete tokens instead of tokens with continuous values.

Turning to FIG. 8, the method (800) for training and the method (850) for sampling are illustrated. The method (800) at step 2 identifies a frame of tokens of an observation. The method (800) at step 3 identifies a random value of uniform noise. The method (800) at step 4 randomly masks a number of tokens proportional to the noise from step 3. The method (800) at step 5 generates another random value. The method at step 6 combines the random noise to a random percentage (calculated from the value from step 5) of tokens. The method (800) at step 7 stores the masked and noised version of the frame of tokens. The method (800) at step trains the model (e.g., a spatio-temporal transformer) to predict the original frame x₀ from the masked and noised frame xₖ. The method (800) at step 9 repeats the preceding steps until the model converges.

The method (850) for sampling (e.g., generating a sample or prediction from a spatio-temporal transformer) at step 1 masks all tokens for the frame to be predicted. The method (850) at steps 2 through 8 perform a sequence of diffusion steps. The method (850) at step 3 generates a prediction using the spatio-temporal transformer. The method (850) at steps 4 and 5 injects noise in the confidence levels for the predicted tokens. The method (850) at step 6 identifies a number of tokens M to demask (e.g., replace the masked values with predicted values). The method (850) at step 7 replaces the masked values with predicted values for the top M tokens (e.g., if M=5, then the five tokens with the highest confidence values are replaced). The method (850) at step 8 triggers repetition of the steps 3 through 7 until all of the tokens in the predicted frame include predicted values instead of masked values. The method (850) at step 9 returns the predicted frame.

With the algorithms of the method (800) and the method (850), a Masked Generative Image Transformer (MaskGIT) may be improved by recasting a MaskGIT as a discrete diffusion model. A lower bound on evidence lower bound (ELBO) under data distribution q(x₀) may be had with the following equation:

$${𝔼}_{q ( {x}_{0} )} [ log {p}_{θ} ( {x}_{0} ) ] \geq {𝔼}_{q ( {x}_{0} )} [ - {ℒ}_{elbo} ( {x}_{0} , θ ) ] \geq {\sum }_{k = 1}^{K} {𝔼}_{q ( {x}_{0} ) q ( {x}_{k} \vert {x}_{0} )} [ log {p}_{θ} ( {x}_{0} \vert {x}_{k} ) ] \qquad Eq . 7$$

For the diffusion posterior q(xₖ|x₀) to be well-defined, uniform label noise in non-masked locations may be used; the loss may be applied not just to masked locations when training the model. Implementing these methods may have the spatio-temporal transformer be an absorbing-uniform discrete diffusion model. During training (e.g., with the method (800)), after masking a random proportion of tokens in x₀, up to y % of uniform noise is injected into the remaining tokens, and a cross entropy loss is applied to reconstruct x₀. During sampling (e.g., with the method (850)), a parallel decoding procedure is followed, but the spatio-temporal transformer model is allowed to iteratively denoise earlier sampled tokens. For conditional generation, classifier-free diffusion guidance may be applied by modifying the logits of p_{θ}, outputs for sampling \tilde{x}₀, and calculating lₖ. Implementation of the disclosure results in an improvement training a single model rather than two separate ones.

Turning to FIG. 9, the table (900) illustrates different aspects of the different objectives used to train a spatio-temporal model. The first objective (902) is “condition on the past, predict the future”. The sequence (905) of frames for the first objective (902) illustrates that the tokens of past frames may be ground truth tokens and the tokens of current and future frames may include masked and noised tokens for training. The past frames do not include masked or noised tokens while the current and future frames may include masked and noised tokens. The attention mask (908) illustrates the mask used to process keys and queries of the spatio-temporal transformer being trained so that tokens of current and past frames may be considered when predicting a token for a current frame. The sequence (910) illustrates that the current and future frames are the targets of the training.

The second objective (952) is “join modeling of the past and the future”. The sequence (955) of frames for the second objective (952) illustrates that the tokens of each of the frames (past, current, and future) may be masked and noised for training to generate predictions for tokens in a current frame. The attention mask (958) may be the same as the attention mask (908). The sequence (910) illustrates that each of the frames (past, current, and future) are the targets of the training.

The third objective (982) is “model each frame individually”. The sequence (985) of frames for the third objective (982) illustrates that the tokens of each of the frames (past, current, and future) may be masked and noised for training to generate predictions for tokens in a current frame. The attention mask (988) is an identity matrix so that only tokens with a current frame may be used to generate predicted tokens for the current frame. The sequence (990) illustrates that each of the frames individually are the targets of the training.

Future prediction may be done via masking, infilling, and further denoising. The model may be trained with a mixture of objectives:
1. 50% of the time, the first objective (902), condition on the past, denoise the future.
2. 40% of the time, the second objective (952), denoise the past and the future jointly.
3. 10% of the time, the third objective (982), denoise each frame individually, regardless of past or future.

The first objective is about future prediction. The second objective also has a future prediction component, but jointly models the future and the past, resulting in a harder pretraining task. The third objective aims to learn an unconditional generative model for applying classifier-free diffusion guidance during inference. The word denoise takes reference to the Algorithm 1 of the method (800) of FIG. 8, where parts of the inputs are first masked and noised, and the model learns to reconstruct the original inputs with a cross-entropy loss. All three objectives may be viewed as maximizing the following:

$${{𝔼}_{q ( τ ) , {k}_{1} , … , {k}_{T \sim SampleObj ( . )}}}_{q ( {x}_{{k}_{1}}^{( 1 )} \vert {x}_{0}^{( 1 )} ) , … q ( {x}_{{k}_{T}}^{( T )} \vert {x}_{0}^{( τ )} )} [ log {p}_{θ} ( {\underbrace{{x}_{0}^{( 1 )} , … , {x}_{0}^{( t - 1 )}}}_{Ignored for Objective type 1} , {x}_{0}^{( t )} , … {x}_{0}^{( T )} \vert {x}_{{k}_{1}}^{( 1 )} , … {x}_{{k}_{T}}^{( T )} , {a}^{( 1 )} , … {a}^{( T - 1 )} ) ] \qquad ( 8 )$$

During inference, one frame at a time may be autoregressively predicted. Each frame is sampled using Algorithm 2 of the method (850) of FIG. 8 with classifier-free diffusion guidance. At each timestep t, the context in diffusion guidance is c^{(t-1)}), which includes the past observation and action history of the agent.

The architecture of the world model is a spatio-temporal transformer that interleaves spatial attention and temporal attention. For spatial attention, a Swin transformer is used on each individual frame. For temporal attention, attention layers (e.g., generative pre-trained transformer (GPT) blocks) may be used to attend over the same feature location across time. A U-Net structure (a machine learning model architecture is characterized by a “U” shape with a contracting path (encoder) followed by an expansive path (decoder)) that combine three levels of feature with residual connections and makes predictions at the same resolution as the initial inputs. Actions (which are the poses of an actor, i.e., an actor may represent a vehicle that may have the sensor that generated the observations) are added to the beginning of each feature level corresponding to their observations, after being flattened and going through two linear layers with layer normalization in between.

The temporal attention mask plays a role in both training and inference. During training, when optimizing the first two types of objectives, causal masking is applied to all temporal transformer layers. When optimizing the third type of objective to learn an unconditional generative model, the temporal attention mask becomes an identity matrix such that each frame attends to itself without attending to the other frames. During inference, the model decodes and denoises one frame at a time. Classifier-free diffusion guidance may be efficiently implemented by increasing temporal sequence length by 1, and setting the attention mask to be a causal mask within the previous sequence length, and an identity mask for the last frame, so that this added frame becomes an unconditional generation.

Turning to FIG. 10, the table (1000), which may be displayed in a user interface on a computing system, illustrates results from using implementations of the disclosure. The observation (1002) is a current observation. The observation (1005) is the future ground truth (e.g., 1 second into the future) for the current observation (the observation (1002)). The observation (1008) is a predicted observation for the same time step as the future ground truth (the observation (1005)). The observation (1010) illustrates the difference between the future ground truth (the observation (1005)) and the predicted observation (the observation (1008)).

The observation (1052) is a current observation and may be the same as the observation (1002). The observations (1055), (1058), and (1060) are different predictions that may occur 3 seconds into the future. Different predictions may be generated using the spatio-temporal transformer from the same set of inputs by the introduction of noise into the steps for selecting tokens to denoise in the diffusion steps performed when sampling with the spatio-temporal transformer, an implementation of which was discussed in the method (850) of FIG. 8.

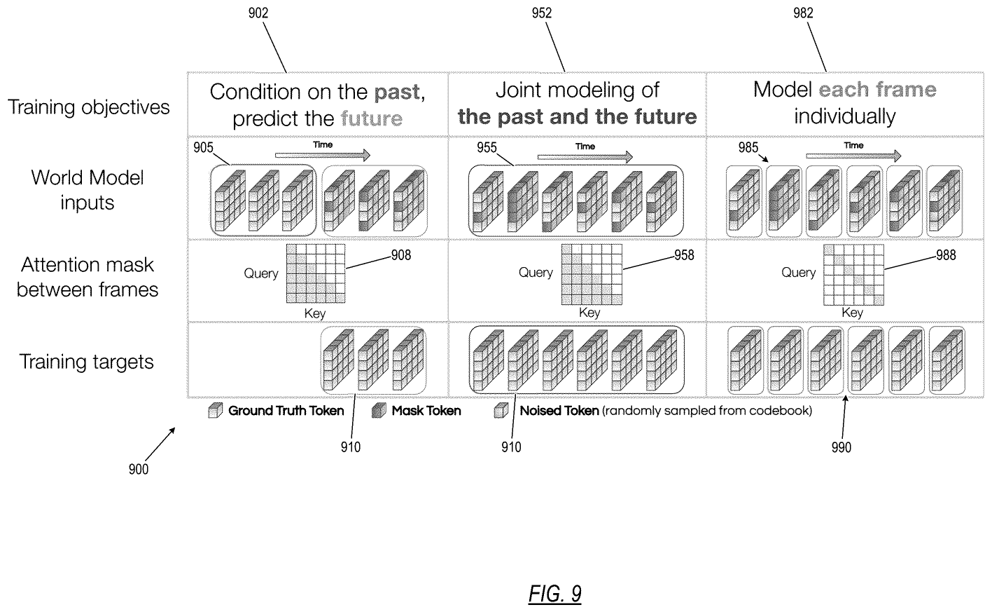

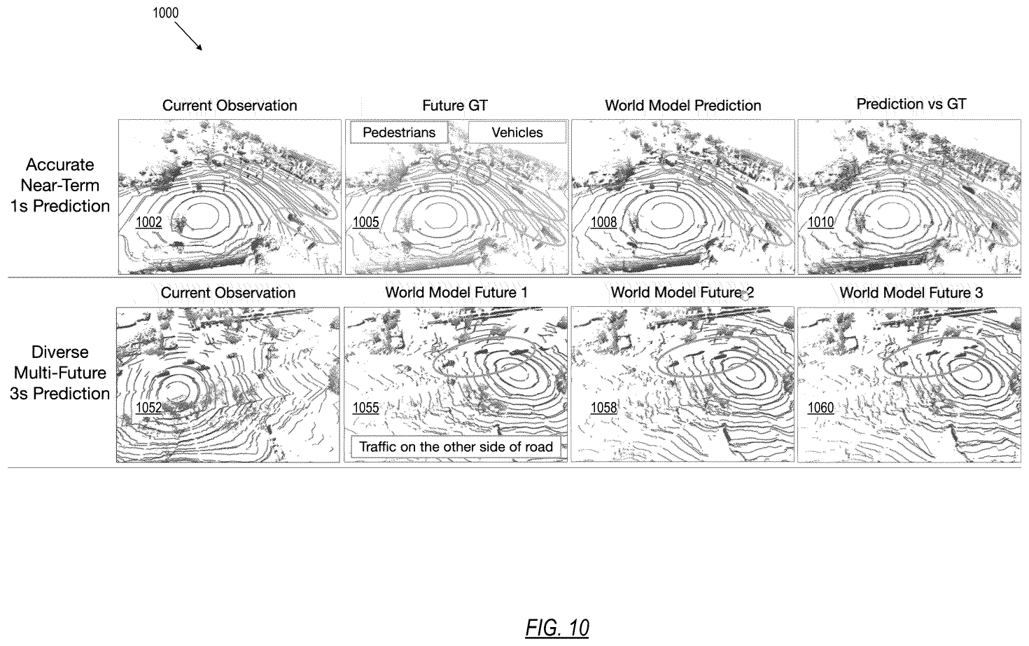

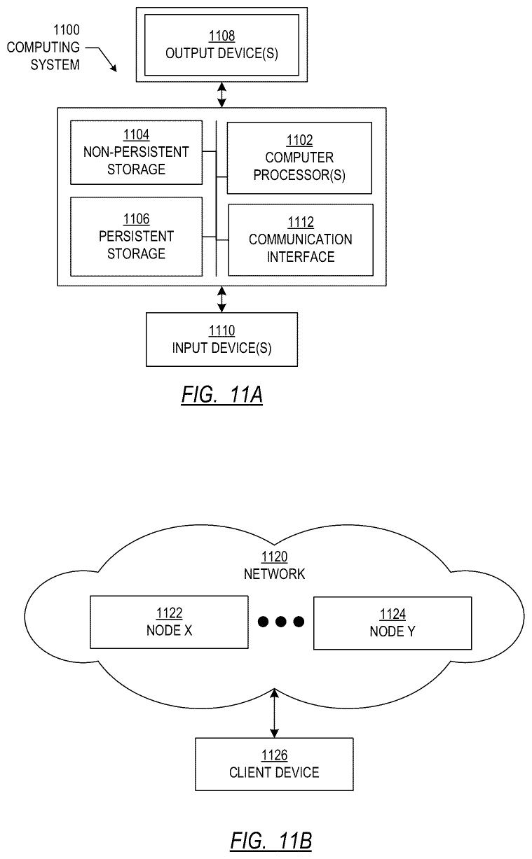

Embodiments may be implemented on a computing system specifically designed to achieve an improved technological result. When implemented in a computing system, the features and elements of the disclosure provide a significant technological advancement over computing systems that do not implement the features and elements of the disclosure. Any combination of mobile, desktop, server, router, switch, embedded device, or other types of hardware may be improved by including the features and elements described in the disclosure. For example, as shown in FIG. 11A, the computing system (1100) may include one or more computer processors (1102), non-persistent storage (1104), persistent storage (1106), a communication interface (1112) (e.g., Bluetooth interface, infrared interface, network interface, optical interface, etc.), and numerous other elements and functionalities that implement the features and elements of the disclosure. The computer processor(s) (1102) may be an integrated circuit for processing instructions. The computer processor(s) may be one or more cores or micro-cores of a processor. The computer processor(s) (1102) includes one or more processors. The one or more processors may include a central processing unit (CPU), a graphics processing unit (GPU), a tensor processing units (TPU), combinations thereof, etc.

The input devices (1110) may include a touchscreen, keyboard, mouse, microphone, touchpad, electronic pen, or any other type of input device. The input devices (1110) may receive inputs from a user that are responsive to data and messages presented by the output devices (1108). The inputs may include text input, audio input, video input, etc., which may be processed and transmitted by the computing system (1100) in accordance with the disclosure. The communication interface (1112) may include an integrated circuit for connecting the computing system (1100) to a network (not shown) (e.g., a local area network (LAN), a wide area network (WAN) such as the Internet, mobile network, or any other type of network) and/or to another device, such as another computing device.

Further, the output devices (1108) may include a display device, a printer, external storage, or any other output device. One or more of the output devices may be the same or different from the input device(s). The input and output device(s) may be locally or remotely connected to the computer processor(s) (1102). Many different types of computing systems exist, and the aforementioned input and output device(s) may take other forms. The output devices (1108) may display data and messages that are transmitted and received by the computing system (1100). The data and messages may include text, audio, video, etc., and include the data and messages described above in the other figures of the disclosure.

Software instructions in the form of computer readable program code to perform embodiments may be stored, in whole or in part, temporarily or permanently, on a non-transitory computer readable medium such as a CD, DVD, storage device, a diskette, a tape, flash memory, physical memory, or any other computer readable storage medium. Specifically, the software instructions may correspond to computer readable program code that, when executed by a processor(s), is configured to perform one or more embodiments, which may include transmitting, receiving, presenting, and displaying data and messages described in the other figures of the disclosure.

The computing system (1100) in FIG. 11A may be connected to or be a part of a network. For example, as shown in FIG. 11B, the network (1120) may include multiple nodes (e.g., node X (1122), node Y (1124)). Each node may correspond to a computing system, such as the computing system shown in FIG. 11A, or a group of nodes combined may correspond to the computing system shown in FIG. 11A. By way of an example, embodiments may be implemented on a node of a distributed system that is connected to other nodes. By way of another example, embodiments may be implemented on a distributed computing system having multiple nodes, where each portion may be located on a different node within the distributed computing system. Further, one or more elements of the aforementioned computing system (1100) may be located at a remote location and connected to the other elements over a network.

The nodes (e.g., node X (1122), node Y (1124)) in the network (1120) may be configured to provide services for a client device (1126), including receiving requests and transmitting responses to the client device (1126). For example, the nodes may be part of a cloud computing system. The client device (1126) may be a computing system, such as the computing system shown in FIG. 11A. Further, the client device (1126) may include and/or perform all or a portion of one or more embodiments.

The computing system of FIG. 11A may include functionality to present raw and/or processed data, such as results of comparisons and other processing. For example, presenting data may be accomplished through various presenting methods. Specifically, data may be presented by being displayed in a user interface, transmitted to a different computing system, and stored. The user interface may include a graphical user interface (GUI) that displays information on a display device. The GUI may include various GUI widgets that organize what data is shown as well as how data is presented to a user. Furthermore, the GUI may present data directly to the user, e.g., data presented as actual data values through text, or rendered by the computing device into a visual representation of the data, such as through visualizing a data model.

As used herein, the term “connected to” contemplates multiple meanings. A connection may be direct or indirect (e.g., through another component or network). A connection may be wired or wireless. A connection may be temporary, permanent, or semi-permanent communication channel between two entities.

The various descriptions of the figures may be combined and may include or be included within the features described in the other figures of the application. The various elements, systems, components, and steps shown in the figures may be omitted, repeated, combined, and/or altered as shown from the figures. Accordingly, the scope of the present disclosure should not be considered limited to the specific arrangements shown in the figures.

In the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

Further, unless expressly stated otherwise, or is an “inclusive or” and, as such includes “and.” Further, items joined by an or may include any combination of the items with any number of each item unless expressly stated otherwise.

In the above description, numerous specific details are set forth in order to provide a more thorough understanding of the disclosure. However, it will be apparent to one of ordinary skill in the art that the technology may be practiced without these specific details. In other instances, well-known features have not been described in detail to avoid unnecessarily complicating the description. Further, other embodiments not explicitly described above can be devised which do not depart from the scope of the claims as disclosed herein. Accordingly, the scope should be limited only by the attached claims.

What is claimed is:

1. A method comprising:
encoding an observation of an actor for a geographic region using an encoder to generate a prior frame of prior tokens;
processing the prior frame with a spatio-temporal transformer to generate a predicted frame of predicted tokens, wherein the spatio-temporal transformer comprises a spatial transformer and a temporal transformer;
processing the predicted frame to generate a predicted action for the actor; and
decoding the predicted frame to generate a predicted observation of the geographic region.

2. The method of claim 1, wherein encoding the observation further comprises:
processing the observation using an encoder transformer, wherein the observation comprises data output from a sensor; and
processing output from the encoder transformer using a quantizer to select the predicted tokens from a codebook.

3. The method of claim 1, wherein processing the prior frame with the spatio-temporal transformer comprises:
processing a spatial set of prior tokens from the prior frame with the spatial transformer to generate a spatial transformer output for a prior token of the spatial set of prior tokens.

4. The method of claim 1, wherein processing the prior frame with the spatio-temporal transformer comprises:
processing a temporal set of prior tokens from a set of prior frames, comprising the prior frame, with the temporal transformer to generate a temporal transformer output for a prior token of the temporal set of prior tokens, wherein the prior token is one of the temporal set of prior tokens and is one of a spatial set of prior tokens.

5. The method of claim 1, wherein processing the prior frame with the spatio-temporal transformer comprises:
executing a diffusion process using the spatio-temporal transformer to generate a sequence of diffusion frames,
wherein the sequence of diffusion frames comprises one or more of a previous diffusion frame, a subsequent diffusion frame, and the predicted frame,
wherein the previous diffusion frame comprises more masked tokens than the subsequent diffusion frame, and
wherein the predicted frame comprises zero masked tokens.

6. The method of claim 1, wherein processing the predicted frame to generate the predicted action comprises:
processing the predicted frame using a pose model to generate an actor pose identifying a pose of an actor that generated the observation.

7. The method of claim 1, wherein decoding the predicted frame comprises:
processing the predicted frame using a decoder transformer comprising an occupancy branch and a probability branch.

8. The method of claim 1, wherein decoding the predicted frame comprises:
processing the predicted frame using an occupancy branch to generate a voxel occupancy value;
processing the predicted frame using a probability branch to generate a voxel point probability; and
processing the voxel occupancy value and the voxel point probability using a renderer to construct the predicted observation from the predicted frame.

9. The method of claim 1, further comprising:
training the spatio-temporal transformer, wherein training the spatio-temporal transformer comprises:
masking a first set of initial tokens within each training frame of a sequence of training frames to form a set of masked tokens within the sequence of training frames,
injecting noise into a second set of initial tokens within each training frame of the sequence of training frames to form a set of noise tokens within the sequence of training frames,
executing the spatio-temporal transformer using the sequence of training frames comprising the set of masked tokens and the set of noise tokens to generate a set of recovered tokens corresponding to the first set of initial tokens and to the second set of initial tokens within the sequence of training frames, and
executing a loss function using cross entropy to update weights of the spatio-temporal transformer to reduce error between the set of recovery tokens with the first set of initial tokens and the second set of initial tokens for subsequent execution of the spatio-temporal transformer.

10. The method of claim 1, further comprising:
training the spatio-temporal transformer with a mixture of objectives by:
executing the spatio-temporal transformer using causal masking of the temporal transformer to recover subsequent frames from previous frames for a first percentage of training executions;
executing the spatio-temporal transformer using causal masking of the temporal transformer to jointly recover the subsequent frames and previous frames for a second percentage of training executions; and
executing the spatio-temporal transformer using an identity matrix with the temporal transformer to recover each training frame individually for a third percentage of training executions,
wherein the first percentage of training executions is greater than the second percentage of training executions, and
wherein the second percentage of training executions is greater than the third percentage of training executions.

11. A system comprising:
at least one processor; and
an application that, when executing on the at least one processor, performs operations comprising:
encoding an observation of an actor for a geographic region using an encoder to generate a prior frame of prior tokens,
processing the prior frame with a spatio-temporal transformer to generate a predicted frame of predicted tokens, wherein the spatio-temporal transformer comprises a spatial transformer and a temporal transformer,
processing the predicted frame to generate a predicted action for the actor, and
decoding the predicted frame to generate a predicted observation of the geographic region.

12. The system of claim 11, wherein encoding the observation further comprises:
processing the observation using an encoder transformer, wherein the observation comprises data output from a sensor; and
processing output from the encoder transformer using a quantizer to select the predicted tokens from a codebook.

13. The system of claim 11, wherein processing the prior frame with the spatio-temporal transformer comprises:
processing a spatial set of prior tokens from the prior frame with the spatial transformer to generate a spatial transformer output for a prior token of the spatial set of prior tokens.

14. The system of claim 11, wherein processing the prior frame with the spatio-temporal transformer comprises:
processing a temporal set of prior tokens from a set of prior frames, comprising the prior frame, with the temporal transformer to generate a temporal transformer output for a prior token of the temporal set of prior tokens, wherein the prior token is one of the temporal set of prior tokens and is one of a spatial set of prior tokens.

15. The system of claim 11, wherein processing the prior frame with the spatio-temporal transformer comprises:
executing a diffusion process using the spatio-temporal transformer to generate a sequence of diffusion frames,
wherein the sequence of diffusion frames comprises one or more of a previous diffusion frame, a subsequent diffusion frame, and the predicted frame,
wherein the previous diffusion frame comprises more masked tokens than the subsequent diffusion frame, and
wherein the predicted frame comprises zero masked tokens.

16. The system of claim 11, wherein processing the predicted frame to generate the predicted action comprises:
processing the predicted frame using a pose model to generate an actor pose identifying a pose of an actor that generated the observation.

17. The system of claim 11, wherein decoding the predicted frame comprises:
processing the predicted frame using a decoder transformer comprising an occupancy branch and a probability branch.

18. The system of claim 11, wherein decoding the predicted frame comprises:
processing the predicted frame using an occupancy branch to generate a voxel occupancy value;
processing the predicted frame using a probability branch to generate a voxel point probability; and
processing the voxel occupancy value and the voxel point probability using a renderer to construct the predicted observation from the predicted frame.

19. The system of claim 11, wherein performing the operations further comprises:
training the spatio-temporal transformer, wherein training the spatio-temporal transformer comprises:
masking a first set of initial tokens within each training frame of a sequence of training frames to form a set of masked tokens within the sequence of training frames,
injecting noise into a second set of initial tokens within each training frame of the sequence of training frames to form a set of noise tokens within the sequence of training frames,
executing the spatio-temporal transformer using the sequence of training frames comprising the set of masked tokens and the set of noise tokens to generate a set of recovered tokens corresponding to the first set of initial tokens and to the second set of initial tokens within the sequence of training frames, and
executing a loss function using cross entropy to update weights of the spatio-temporal transformer to reduce error between the set of recovery tokens with the first set of initial tokens and the second set of initial tokens for subsequent execution of the spatio-temporal transformer.

20. A non-transitory computer readable medium comprising instructions executable by at least one processor to perform operations comprising:
encoding an observation of an actor for a geographic region using an encoder to generate a prior frame of prior tokens;
processing the prior frame with a spatio-temporal transformer to generate a predicted frame of predicted tokens, wherein the spatio-temporal transformer comprises a spatial transformer and a temporal transformer;
processing the predicted frame to generate a predicted action for the actor; and
decoding the predicted frame to generate a predicted observation of the geographic region.
